(19) United States
(12) Patent Application Publication
(10) Pub. No.: US 2019/0006459 A1
(43) Pub. Date: Jan. 3, 2019

(54) High-Dielectric Constant Capacitor Structures on III-V Substrates

(71) Applicant: Avago Technologies General IP (Singapore) Pte. Ltd., Singapore (SG)

(72) Inventors: Satish Yeldandi, Fort Collins, CO (US); Phil Nikkel, Loveland, CO (US); Thomas Dungan, Fort Collins, CO (US); Jonathan Abrokwah, Fort Collins, CO (US)

(21) Appl. No.: 15/635,406

(22) Filed: Jun. 28, 2017

(51) Int. Cl. H01L 49/02; H01L 21/02; H01L 27/06; H01L 29/06; H01L 29/20

(52) U.S. Cl. CPC H01L 28/75; H01L 21/02183; H01L 21/02167; H01L 27/0605; H01L 21/02266; H01L 29/20; H01L 21/02181; H01L 21/02274; H01L 21/0228; H01L 29/0692

(57) ABSTRACT

A semiconductor structure includes a III-V semiconductor structure; a first electrode; a first barrier layer disposed over the first electrode; a first adhesion layer disposed over the first electrode; a first passivation layer disposed over the first adhesion layer; a dielectric layer disposed over the first passivation layer; a second passivation layer disposed over the dielectric layer; a second adhesion layer disposed over the second passivation layer; a second barrier layer disposed over the second adhesion layer; and a second electrode disposed over the second barrier layer.

### BACKGROUND

Wireless communications devices including radio-frequency (RF), microwave, and millimeter wave devices are often constructed from Group III-V semiconductor materials, such as GaAs or GaAs alloys or InP or InP alloys, and are commonly employed in wireless communication systems. These wireless communication devices may include power amplifiers, low noise amplifiers, switches, and other similar devices, and can be included in integrated circuits such as monolithic microwave/millimeter wave integrated circuits (MMICs).

With the increased demand for greater functionality often in a smaller footprint in wireless communication devices, there is increased demand for a reduction in die size for devices and ICs generally. For example, power amplifier die sizes have continued to decrease over the last few decades in an effort to meet the increased demands in function, and in a smaller overall component (e.g., mobile phone). Besides the active transistor components such as heterojunction bipolar transistors (HBTs), and high-electron mobility transistors (HEMTs), such as pseudomorphic HEMTs (pHEMTs), the accompanying circuits of power amplifiers require capacitors, resistors, and diodes for impedance matching, decoupling, bias setting, electrostatic discharge protection, and the like.

In known power amplifiers, capacitors often include silicon nitride (Si₃N₄) as the dielectric layer, which is deposited using plasma enhanced chemical vapor deposition (PECVD). Such capacitors often consume a significant die area, on the order of 10% to 50% depending on the circuit. III-V wafers and associated specialty fabrication processes are relatively expensive (compared, for example, with silicon-based integrated circuit processes) and the reduction of the area and volume of mobile phone components is always desired to enable smaller handsets, or to provide more space for other components (such as batteries) within an existing handset size. Capacitors used in handset RF power amplifiers often are required to maintain high breakdown voltages, to survive electrical stress during operation of the amplifier under mismatched output load conditions, and to simplify electrostatic-discharge protection design. These requirements for high breakdown voltage preclude reducing the thickness of conventional capacitor dielectrics (such as PECVD silicon nitride) below fixed thicknesses (dependent on the specific RF module design) in order to increase their areal capacitance density.

What is needed, therefore, is a capacitor structure for integration into III-V wireless power amplifier devices that overcomes at least the shortcomings of known capacitors described above.

### BRIEF DESCRIPTION OF THE DRAWINGS

The representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional view of a capacitor structure in accordance with a representative embodiment.

FIGS. 2A-2C are cross-sectional views of a fabrication sequence of a semiconductor structure according to a representative embodiment.

FIG. 3 is a cross-sectional view of a semiconductor structure according to a representative embodiment.

FIG. 4 is a perspective view of a semiconductor structure according to a representative embodiment.

FIG. 5 is a graph showing the capacitance of a known capacitor, and of capacitors of the present teachings.

FIG. 6 is a graph showing the capacitance versus area of overlap of a known capacitor, and of capacitors of the present teachings.

FIG. 7 is a graph showing breakdown voltage versus probability of a known capacitor, and of capacitors of the present teachings.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

The described embodiments relate generally to a semiconductor structure, comprising: a III-V semiconductor structure; a first electrode; a first barrier layer disposed over the first electrode; a first adhesion layer disposed over the first electrode; a first passivation layer disposed over the first adhesion layer; a dielectric layer disposed over the first passivation layer; a second passivation layer disposed over the dielectric layer; a second adhesion layer disposed over the second passivation layer; a second barrier layer disposed over the second adhesion layer; and a second electrode disposed over the second barrier layer.

In certain representative embodiments described more fully below, the dielectric layer has a dielectric constant in the range of approximately 20 to approximately 25. Beneficially, since the capacitance of a parallel plate capacitor is directly proportional to the dielectric constant, and the area of the contacting overlap of the electrodes and dielectric layer, the comparatively high dielectric constant of the dielectric layer of the capacitor structures of the present teachings allows the formation of a capacitor having a same capacitance as a known capacitor having a dielectric layer having a comparatively low dielectric constant, but having an areal dimension that is reduced by a factor of the ratio of the comparatively high dielectric constant material, and the comparatively low dielectric material. Moreover, and as will be described more fully below, since the capacitance of a parallel plate capacitor is inversely proportional to the distance between the parallel plate electrodes (i.e., the thickness of the dielectric material), a trade-off can be made between the desired reduction of the area of overlap of the electrodes and dielectric layer of the capacitor, and a desired increase in the breakdown voltage (BVD) of the capacitor structure of the present teachings.

Beneficially, integration features afforded by the implementation of the high-k dielectric materials used in capacitors of the present teachings, for integration with III-V semiconductor fabrication, are a low deposition temperature (e.g., less than approximately 300° C.) compatible with III-V processing, where ohmic contacts often comprise AuGeNi typically alloyed at 420° C. or less; and a high enough dielectric breakdown to ensure capacitor survival during elevated voltages that might be experienced during operation of the amplifier under mismatched load conditions or during an electrostatic discharge event. In addition to a sufficiently high nominal breakdown voltage to meet these requirements, the capacitor fabrication process must ensure that the entire distribution of manufactured capacitors will meet the breakdown requirements with low capacitor defectivity. As described more fully below, in accordance with certain representative embodiments, the dielectric materials used for the dielectric layers of the capacitors of the present teachings are close to a stoichiometric dielectric to ensure low capacitor dielectric loss.

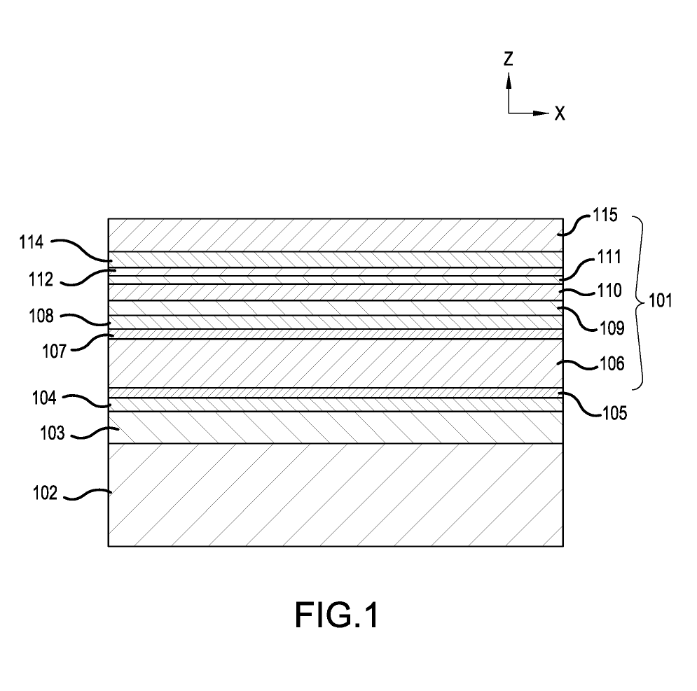

FIG. 1 is a cross-sectional view of a semiconductor structure 100 comprising a capacitor 101 in accordance with a representative embodiment. The capacitor 101 of the present teachings generally comprises the various layers described more fully below, and is disposed between a first electrode 106 and a second electrode 115. As used herein, an area of the capacitor 101 comprises a contacting overlap between the first electrode 106, the second electrode 115, and layers, which are described more fully below, disposed between the first electrode 106 and the second electrode 115. The area or areal dimensions of the capacitor 101 are measured in a plane in the x-y direction of the coordinate system of FIG. 1. Beneficially, and as described more fully below, the area of the capacitor 101 is smaller than those of known capacitors used in semiconductor structures because of the use of a comparatively high dielectric constant used for a dielectric layer 110. By way of example, the dielectric layer 110 has a comparatively high relative permittivity (εᵣ), and therefore a comparatively high dielectric constant (k) that is approximately 3.6 times that of Si₃N₄, which is commonly used in known capacitors in similar semiconductor structures to those described in accordance with the present teachings. The capacitance of a parallel plate capacitor is directly proportional to the area of the capacitor, and inversely proportional to the dielectric constant, and the distance between the parallel plate electrodes (and thus, the thickness of the dielectric layer between the parallel plate electrodes). Accordingly, by selecting the dielectric layer 110 to have a comparatively high dielectric constant (k), the area of the capacitor 101 can be reduced significantly compared to a known capacitor having a plasma-enhanced chemical vapor deposited (PECVD) Sᵢ₃N₄ dielectric layer. Moreover, and as described more fully below, the thickness of the dielectric layer 110 can be selected to provide capacitor 101 with a similar breakdown voltage to that of a known capacitor having a PECVD Sᵢ₃N₄ dielectric layer, while having an areal dimension that is at least one-half of an area of the known capacitor having a PECVD Sᵢ₃N₄ dielectric layer, and having the same capacitance, and a similar magnitude breakdown voltage.

The semiconductor structure 100 comprises a substrate 102, which may be selected based on the active semiconductor devices fabricated therefrom. Generally, the substrate 102 comprises a semiconductor material. Illustrative semiconductor materials for the substrate 102 include binary Group III-V semiconductor materials (e.g., GaAs) and ternary Group III-V semiconductor materials (e.g., InGaP). Notably, other structures and materials are contemplated for use as the substrate 102. For example, the substrate 102 may be a multilayer substrate comprising materials and structures suitable for use in a desired application. Further details of certain contemplated structures and materials are described in U.S. Pat. No. 8,946,904 to Parkhurst, et al., the disclosure of which is specifically incorporated herein by reference.

A layer 103 is disposed over the substrate 102. The layer 103 illustratively comprises PECVD silicon nitride (Si₃N₄) having a thickness range of approximately 1000 Å to approximately 3000 Å, or other suitable material, including but not limited to silicon dioxide (SiO₂) or silicon oxynitride (SiON). The layer 103 provides passivation, and a comparatively smooth upper surface over which the remainder of the semiconductor structure can be formed.

The semiconductor structure 100 further comprises a first adhesion layer 104 disposed over the layer 103, a first passivation layer 105, and the first electrode 106. The first adhesion layer 104 is selected to ensure suitable adhesion to the layer 103, and thereby prevent delamination of the capacitor 101 from the substrate 102. In a representative embodiment, where the layer 103 comprises Si₃N₄, the first adhesion layer 104 comprises titanium (Ti) formed using a known method (e.g., electron beam evaporation) having a thickness of approximately 300 Å to approximately 600 Å.

Generally, in III-V semiconductor structures, electrodes are fabricated from comparatively soft metals, such as Gold (Au). As such, in accordance with a representative embodiment, the first electrode 106 comprises gold having a thickness in the range of approximately 3000 Å to approximately 1.0 μm. Illustratively, the first electrode 106 is formed using a known processing sequence including a lift-off photoresist patterning step, metal evaporation, and lift off.

To prevent inter-diffusion of titanium from the first adhesion layer 104 through to the gold, the first passivation layer 105 comprises a suitable passivation material such as platinum (Pt), formed using a known method (e.g., electron beam evaporation) having a thickness of approximately 300 Å to approximately 600 Å, preferably 500 Å

A second passivation layer 107 is disposed over the first electrode 106, and continuing with the illustrative materials, the second passivation layer 107 comprises platinum. A second adhesion layer 108 is disposed over the second passivation layer 107. A first barrier layer 109 is disposed over the second adhesion layer 108, and a dielectric layer 110 is disposed over the first barrier layer 109.

In addition to deterring diffusion of titanium from the first and second adhesion layers 104, 108 through to the (gold) first and second electrodes 106, 115, respectively, use of platinum for the first and second passivation layers 105, 107 provides a comparatively hard, and smooth surface, which is beneficial during fabrication of the semiconductor structure 100, and to the final product. To this end, the comparatively hard platinum first and second passivation layers 105, 107 protect underlying layers from scratching during subsequent processing steps used in III-V semiconductor device fabrication, such as lift-off methods.

Moreover, the platinum first and second passivation layers 105, 107 reduce the overall defectivity. As is known, defects in a capacitor can function as electrical shorts, and can degrade/decrease the breakdown voltage of the capacitor. By reducing the overall defectivity from scratches on the metal surface from lift-off process, as well as irregularities on the surface from the metal evaporation process, and using platinum for the first and second passivation layers 105, 107, the breakdown voltage of the capacitor 101 can be improved compared to known capacitors.

As noted above, the dielectric layer 110 is selected to have a comparatively high relative permittivity (εᵣ), and therefore a comparatively high dielectric constant (k). Illustratively, the dielectric layer 110 has a dielectric constant in the range of approximately 20 to approximately 25. In certain representative embodiments, the dielectric layer 110 comprises tantalum pentoxide (Ta₂O₅), which has a dielectric constant of approximately 22. Alternatively, the dielectric layer 110 may comprise hafnium dioxide (HfO₂), which has a dielectric constant of approximately 25.

In accordance with representative embodiments, the Ta₂O₅ and HfO₂ are beneficially high-quality, or stoichiometric layers. To this end, the more amorphous the Ta₂O₅ and HfO₂ layers are, the better the quality of the dielectric layer 110. Similarly, unattached tantalum, or hafnium, as well as other defects reduce the quality of the respective dielectric materials, which can result in a degradation of the dielectric layer 110 in the form of a reduced breakdown voltage. Using atomic layer deposition (ALD) provides a material that is substantially stoichiometric, substantially amorphous, substantially homogeneous, comparatively dense, and has a reduced level of defects. Alternatively, reactive sputtering, such as DC sputtering of a metal target in oxygen plasma can be used. However, and while not wishing to be bound to theory, Applicants surmise that the sputter deposited Ta₂O₅ and HfO₂, may not be as homogeneous as ALD deposited Ta₂O₅ and HfO₂. As described more fully below, this may result in a capacitance density that is less than that of ALD Ta₂O₅ and HfO₂. Illustratively, the dielectric layer 110 comprising Ta₂O₅ or HfO₂ has a thickness in the range of approximately 950 Å to approximately 1250 Å. As will be appreciated by one of ordinary skill in the art, amorphous, and homogeneous films may be characterized by well-known techniques such as ellipsometry and X-ray photoelectron spectroscopy, while the electrical breakdown quality can be assessed with Vramp characterization. Notably, the oxidation state of the Ta₂O₅ layer or HfO₂ layer can be assessed with X-ray photoelectron spectroscopy. Beneficially, the dielectric layer 110 formed by ALD is substantially void of free metals (i.e., substantially free of unoxidized or elemental Ta in the case Ta₂O₅ is used for the dielectric layer 110; or substantially free of unoxidized or elemental Hf in the case HfO₂ is used for dielectric layer 110.

Notably, the selection of Ta₂O₅ or HfO₂ further illustrates the benefit of the first adhesion layer 104. Specifically, neither Ta₂O₅ nor HfO₂, if having little unbound tantalum or hafnium, will properly adhere to the first electrode 106, which is illustratively gold. The first adhesion layer 104 provides suitable adhesion. While providing suitable adhesion, use of the first adhesion layer 104 (e.g., titanium) in the capacitor 101 requires the first barrier layer 109 to prevent oxidation of the metal (Ti) in the first adhesion layer 104 by the tantalum or hafnium in the dielectric layer 110, because of the relatively low oxidation energy of titanium to those of tantalum or hafnium. In accordance with a representative embodiment, the first barrier layer 109 comprises silicon nitride (Si₃N₄) illustratively deposited by PECVD, and having a thickness in the range of approximately 15 Å to approximately 50 Å.

A second barrier layer 111 is disposed over the dielectric layer 110; a second adhesion layer 112 is disposed over the second barrier layer 111; a second passivation layer 114 is disposed over the second adhesion layer 112; and the second electrode 115 is disposed over the second passivation layer 114. The second electrode 115 comprises gold having a thickness in the range of approximately 3000 Å to approximately 1.4 μm. Illustratively, the second electrode 115 is formed using a known processing sequence including a lift-off photoresist patterning step, metal evaporation, and lift off.

Like first barrier layer 109, second barrier layer 111 prevents oxidation of the second adhesion layer 112 by the dielectric layer 110, should a material like Ta₂O₅ be used. Illustratively, the second barrier layer 111 comprises Si₃N₄, also illustratively deposited by PECVD, and having a thickness in the range of approximately 15 Å to approximately 50 Å.

Similarly, like first adhesion layer 104, the second adhesion layer 112 prevents delamination of the second electrode 115, which is illustratively gold. Specifically, if either Ta₂O₅ or HfO₂ are used for the dielectric layer 110, if having little unbound tantalum or hafnium, these materials will not properly adhere to the second electrode 115, which is also illustratively gold. The second adhesion layer 112 provides suitable adhesion. Like the first adhesion layer 104, while providing suitable adhesion, use of the second adhesion layer 112 (e.g., titanium) in the capacitor 101 requires the second barrier layer 111 to prevent oxidation of the metal (Ti) in the second adhesion layer 112 by the tantalum or hafnium in the dielectric layer 110, because of the relatively low oxidation energy of titanium to those of tantalum or hafnium.

Finally, like first passivation layer 105, second passivation layer 114 prevents inter-diffusion of titanium from the second adhesion layer 108 through to the second electrode 115, which is illustratively gold. As such, the second passivation layer 114 comprises a suitable passivation material such as platinum (Pt). Illustratively, the platinum of the second passivation layer 114 is formed using a known method (e.g., evaporation), and has a thickness of approximately 300 Å to 600 Å. In certain embodiments, a thickness of the platinum of the second passivation layer 114 of approximately 500 Å is beneficial.

While the illustrative dielectric materials used for the dielectric layer 110 enable a greater reduction in area of the capacitor 101, as described more fully below, their bandgap energies, and consequently their breakdown voltages are comparatively low. To this end, the proposed high-K dielectric materials used for the dielectric layer 110 generally have lower dielectric strength compared to Si₃N₄. For example, while known PECVD Si₃N₄ has a breakdown strength of approximately 9 MV/cm, substantially stoichiometric Ta₂O₅ has a strength of about 5 MV/cm. As such, other dielectric materials, such as alumina (Al₂O₃), which has a comparatively low dielectric constant, but is still greater than known materials (e.g., Si₃N₄), which are used as the dielectric layer in known capacitors, may be used. While providing a smaller areal reduction in the capacitor 101 compared to Ta₂O₅ or HfO₂, Al₂O₃ has a beneficially, comparatively high breakdown voltage for the same thickness (z-dimension in the coordinate system of FIG. 1).

Alternatively, and as described further below, for the same capacitance as a known capacitor having known materials (e.g., Si₃N₄) used as the dielectric layer and as described further below, providing a thicker layer of Ta₂O₅ or HfO₂, which reduces the electric field strength across the dielectric layer 110, while reducing the gain in reduction of the area of the capacitor 101, improves the breakdown voltage. Since the dielectric constant ratio is about 3.6 for Ta₂O₅, the capacitor thickness can be chosen higher than Si₃N₄ to realize equivalent stack dielectric breakdown comparable to Si₃N₄. As such, by the present teachings, by selection of the thickness of the high-k dielectric layer 110, a trade-off can be made allowing an acceptable reduction in the area of the capacitor 101, and an acceptable breakdown voltage. As noted above and described further below, the thickness of the dielectric layer 110 can be selected to provide capacitor 101 with a similar breakdown voltage to that of a known capacitor having a PECVD Si₃N₄ dielectric layer, while having an areal dimension that is at least one-half of an area of the known capacitor having a PECVD Si₃N₄ dielectric layer, and having the same capacitance, and a similar magnitude breakdown voltage.

Accordingly, by the present teachings, the area of the capacitor 101 and the thickness of the dielectric layer 110 are parameters that can be adjusted to select the desired area and breakdown voltage for capacitor 101, while having the same capacitance as a known capacitor having a PECVD Si₃N₄ dielectric layer.

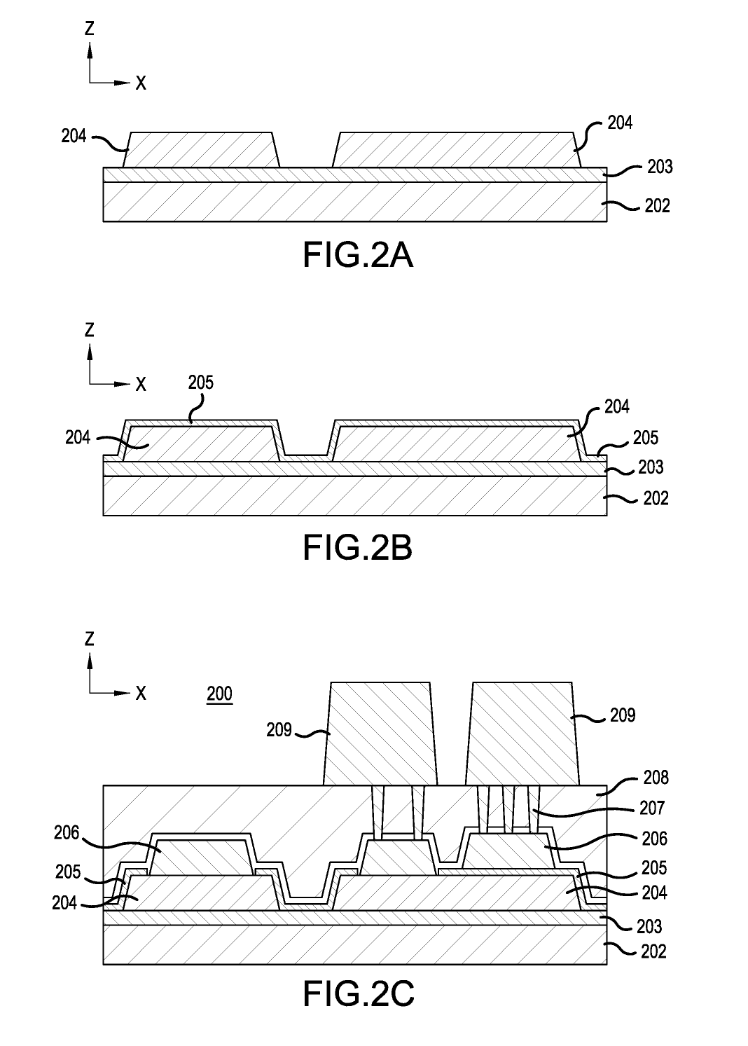

FIGS. 2A-2C are cross-sectional views of a fabrication sequence of a semiconductor structure 200 according to a representative embodiment. Many aspects and details of the semiconductor structure 200 are common to those of the semiconductor structure 100, and may not be repeated.

FIG. 2A shows a substrate 202, which may be selected based on the active semiconductor devices fabricated therefrom. Generally, the substrate 202 comprises a semiconductor material. Illustrative semiconductor materials for the substrate 202 include binary Group III-V semiconductor materials (e.g., GaAs), and ternary Group III-V semiconductor materials (e.g., InGaP).

A layer 203 is disposed over the substrate 202. The layer 203 illustratively comprises silicon nitride (Si₃N₄), or other suitable material, and provides passivation, and a comparatively smooth upper surface over which the remainder of the semiconductor structure 200 can be formed. Although not shown in FIG. 2A, the first adhesion layer 104 is disposed over the layer 203, and the first passivation layer 105 is disposed over the first adhesion layer 104.

First electrodes 204 are disposed over a first adhesion layer (not shown in FIG. 2A), and a first passivation layer (not shown in FIG. 2A) which comprise the same materials and serve the same function as the first adhesion layer 104, and the first passivation layer 105 described above. Like the first electrode 106, the first electrodes 204 comprise gold having a thickness in the range of approximately 3000 Å to 1.0 μm and formed using a known processing sequence including a lift-off photoresist patterning step, metal evaporation, and lift off.

FIG. 2B shows a stack 205 disposed over the first electrodes 204. The stack 205 comprises, in order from bottom to top (+Z direction in the coordinate system depicted in FIGS. 2A-2C), the second passivation layer 107 disposed over the first electrodes 204; the second adhesion layer 108 disposed over the second passivation layer 107; the first barrier layer 109 disposed over the second adhesion layer 108; the dielectric layer 110 disposed over the first barrier layer 109; the second barrier layer 111 disposed over the dielectric layer 110; the second adhesion layer 112 disposed over the second barrier layer 111; and the second passivation layer 114 disposed over the second adhesion layer 112.

FIG. 2C shows second electrodes 206 (also referred to as the top cap layers) disposed over the stack 205. The second electrodes 206 comprise gold having a thickness in the range of approximately 3000 Å to 1.4 μm. Illustratively, the second electrodes 206 are formed using a known processing sequence including a lift-off photoresist patterning step, metal evaporation, and lift off.

After the second electrodes 206 are formed, a dielectric layer 207 is disposed over the underlying structure. The dielectric layer 207 may comprise a layer of benzocyclobutene (BCB) or polyimide that is “spun on” to a desired thickness. The dielectric layer 207 provides a substantially planar surface over which subsequent components are disposed.

After the dielectric layer 207 is formed, openings for vias are etched into the dielectric layer 207 using a known plasma etch method, and electrically conductive vias 208 are provided in the openings by evaporation or plating of a suitable material including a suitable metal (e.g., Au), or a suitable alloy. Next, a second metal layer 209 (Metal II Layer) is disposed over the dielectric layer 207, and provides electrical connection to the capacitor structure comprising the first electrode 204, the stack 205, and the second electrode 206. The second metal layer 209 may then be connected to an active electronic or optoelectronic semiconductor device (not shown in FIG. 2C) disposed in a ‘flip-chip’ arrangement, and connected to the second metal layer 209 via a conductive pillar (not shown in FIG. 2C). The conductive pillar may connect signal lines to the active semiconductor device, or may connect the active semiconductor device to ground. As is known, a plurality of conductive pillars may be used to effect signal and ground connections. Further details of the use of conductive pillars may be found in U.S. Pat. No. 8,314,472 to Parkhurst, et al.; and U.S. Pat. Nos. 8,344,504, and 8,536,707 to Wholey, et al., the entire disclosures of which are specifically incorporated herein by reference in their entirety.

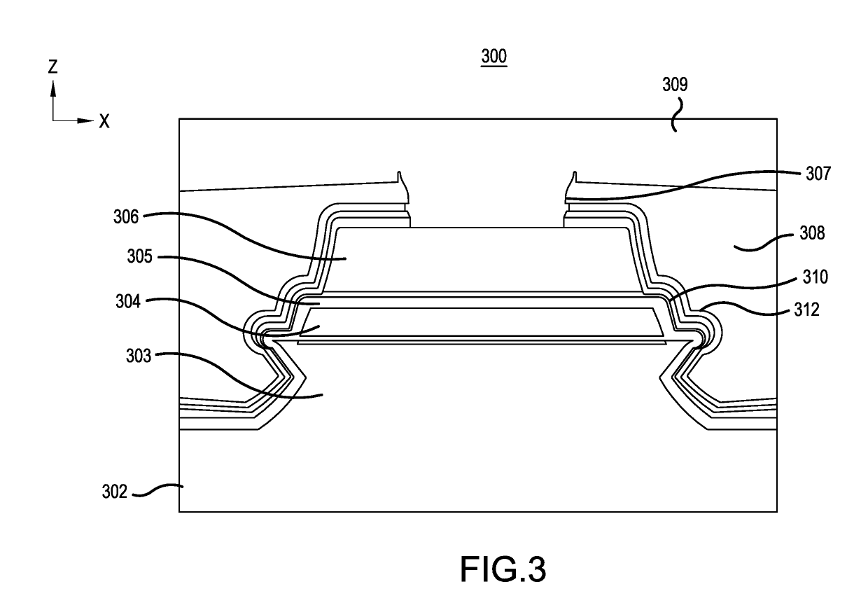

FIG. 3 is an illustration of an edge cross-sectional view of a semiconductor structure 300 of an active transistor according to a representative embodiment. Notably, in some embodiments, capacitors of the present teachings are integrated with active transistors such as heterojunction bipolar devices, in a manner described presently. Aspects and details of the semiconductor structure 300 are common to those of the semiconductor structures 100 and 200, and may not be repeated, but equivalent layers are noted.

The semiconductor structure 300 comprises a substrate 302. The substrate 302 comprises a semiconductor material. Illustrative semiconductor materials for the substrate 302 include binary Group III-V semiconductor materials (e.g., GaAs) and ternary Group III-V semiconductor materials (e.g., InGaP).

A semiconductor (illustratively III-V semiconductor) mesa 303 is disposed over the substrate 302. The semiconductor mesa 303 comprises portions of an active semiconductor device, in this case a transistor (not fully shown in FIG. 3), such as an HBT. Specifically, FIG. 3 depicts an edge cross-sectional view that shows a first electrode 304 (sometimes referred to as a base metallization), which comprises gold, and having a titanium layer (not discernible in FIG. 3) and a platinum layer 310. The platinum layer 310 is diffused into the semiconductor by a subsequent annealing process for the base ohmic formation. A stack 305, which is substantively the same as stack 205 described above, is disposed over a first electrode 304, and a second electrode 306 (sometimes referred to as interconnect metallization), which is substantively the same as first electrode 106, is disposed over the stack 305.

Illustratively, the stack 305 comprises Si₃N₄/Ta₂O₅/ Si₃N₄ or Si₃N₄/HfO₂/Si₃N₄. A dielectric layer 312 is comprised of a PECVD Si₃N₄ Nitride 3, and a layer 308 is illustratively a BCB layer, such described above in connection with FIGS. 2A-2C. Due to the high resistivity and insulating properties of the stack 305, there is no need to remove the dielectric layers around the semiconductor mesa 303. However, appropriate via connections to contact the first electrode 304, requires a successful plasma to etch layer 308 (e.g., BCB), nitrides and high-K materials in the openings for vias (e.g., via 307, which connects to metal II layer 309).

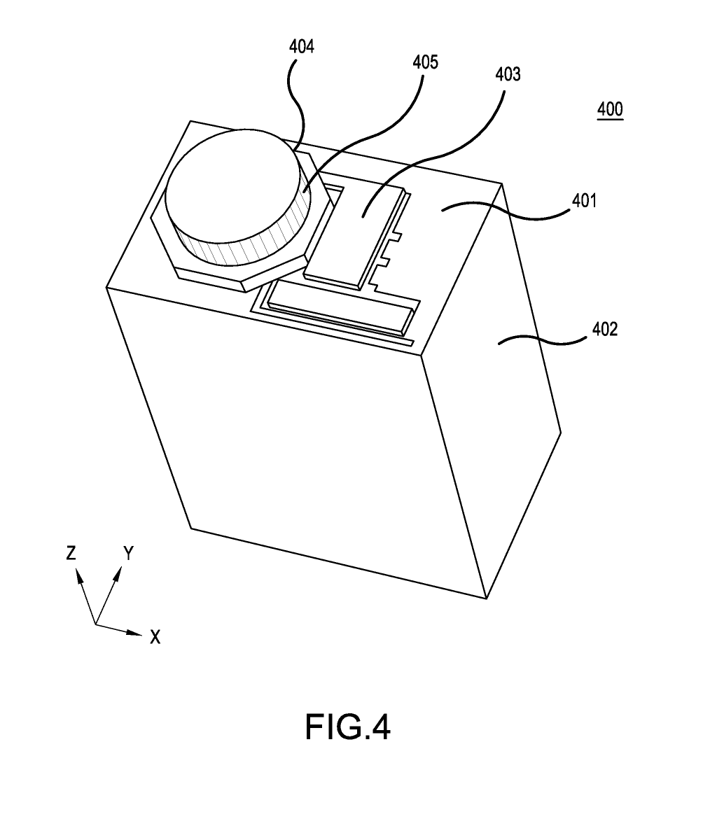

FIG. 4 is a perspective view of a semiconductor structure 400 according to a representative embodiment. Many aspects and details of the semiconductor structure 400 are common to those of the semiconductor structures 100, 200 and 300, and may not be repeated.

A capacitor 401 is disposed over an upper surface of a substrate 402. The capacitor 401 comprises a first electrode (not shown in FIG. 4), a stack (not shown in FIG. 4) disposed over the first electrode, and a second electrode 403. The stack comprises the second passivation layer 107 disposed over the first electrode 204; the second adhesion layer 108 disposed over the second passivation layer 107; the first barrier layer 109 disposed over the second adhesion layer 108; the dielectric layer 110 disposed over the first barrier layer 109; the second barrier layer 111 disposed over the dielectric layer 110; the second adhesion layer 112 disposed over the second barrier layer 111; and the second passivation layer 114 disposed over the second adhesion layer 112.

The semiconductor structure 400 also comprises an electrically conductive pillar 404 disposed over the upper surface of the substrate 402, and adapted to effect electrical connections between active electronic or optoelectronic devices disposed in the substrate 402 (not shown in FIG. 4), the capacitor 401, and other devices (not shown in FIG. 4), such as an electronic or optoelectronic device disposed in a flip-chip manner, as described above.

Beneficially, the capacitor 401 with capacitance density a few times higher than a capacitor having a PECVD silicon nitride dielectric layer reduces capacitor die size, enabling further shrinkage of power amplifier die size. Flip chip designs of power amplifiers enable the overall footprint of amplifiers to be reduced. Cu-pillars used in flip-chip designs are a way to decrease die foot print, and reduce thermal resistances. As such, designs approaching pillar-limited spaces can benefit by use of the smaller capacitor sizes of the present teachings to facilitate the smaller die size, while maintaining performance. Again, further details of the use of conductive pillars may be found in the above incorporated U.S. Pat. Nos. 8,314,472, 8,344,504, and 8,536,707.

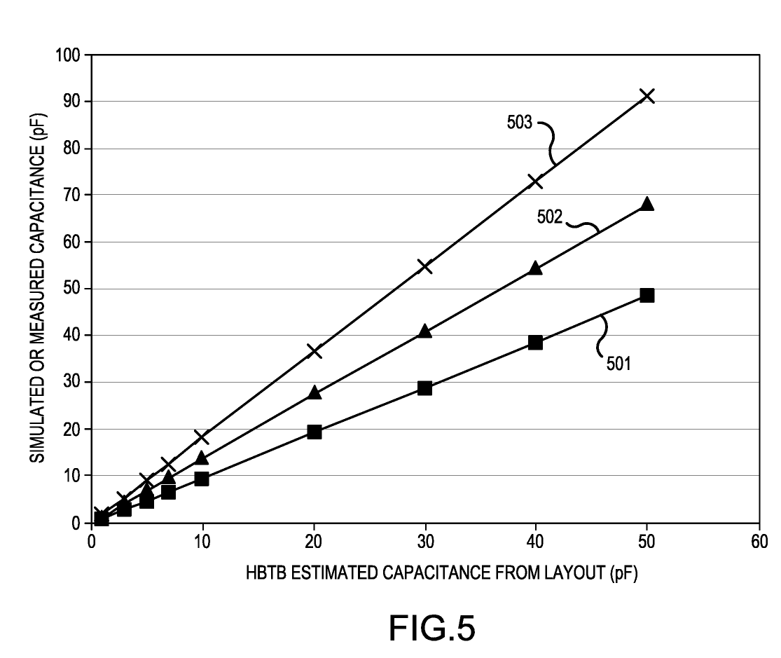

FIG. 5 is a graph showing the capacitance of a known capacitor, and of capacitors of the present teachings. The capacitors described in connection with FIG. 5 have the same area.

Curve 501 shows the measured or simulated capacitance versus expected capacitance of a known capacitor having a PECVD silicon nitride dielectric layer with a thickness of 710 Å.

Curve 502 shows the measured or simulated capacitance versus expected capacitance of a capacitor in accordance with a representative embodiment, and comprising the first adhesion layers, the first and second barrier layers discussed above; and a first passivation layer comprising 50 Å Si₃N₄, a 900 Å Ta₂O₅ dielectric layer, and a 50 Å Si₃N₄ second passivation layer. Notably, the dielectric layer of the capacitor of curve 502 was fabricated using a known sputtering method.

Curve 503 shows the measured or simulated capacitance versus expected capacitance of a capacitor in accordance with a representative embodiment, and comprising the first adhesion layers, the first and second barrier layers discussed above; a first passivation layer comprising 50 Å Si₃N₄, a first passivation layer, a 900 Å Ta₂O₅ dielectric layer, and a 50 Å Si₃N₄ second passivation layer. Notably, the dielectric layer of the capacitor of curve 503 was fabricated using atomic layer deposition (ALD).

As can be appreciated, for a particular capacitor area, the capacitance of curves 502 and 503 of the capacitors of the present teachings is significantly greater than that of the known capacitor. Moreover, the capacitor having the ALD dielectric layer has a substantially greater capacitance than the other capacitors. As noted above, Applicants surmise that the sputter deposited Ta₂O₅ and HfO₂ may not be as homogeneous as ALD deposited Ta₂O₅, and may result in a capacitance density that is less than that of ALD Ta₂O₅. However, the sputter deposited Ta₂O₅ of the capacitor of curve 502 provides a significant improvement in capacitance per unit area compared to the known capacitor of curve 501.

As can be appreciated by the present teachings, a capacitor can be provided that has the same capacitance as a known capacitor having a PECVD silicon nitride dielectric layer, but having a significantly reduced area. Moreover, and as noted above, the breakdown voltage of the capacitors of the present teachings can be improved by increasing the thickness of the dielectric layer, allowing a compromise in the area of the capacitor and the breakdown voltage.

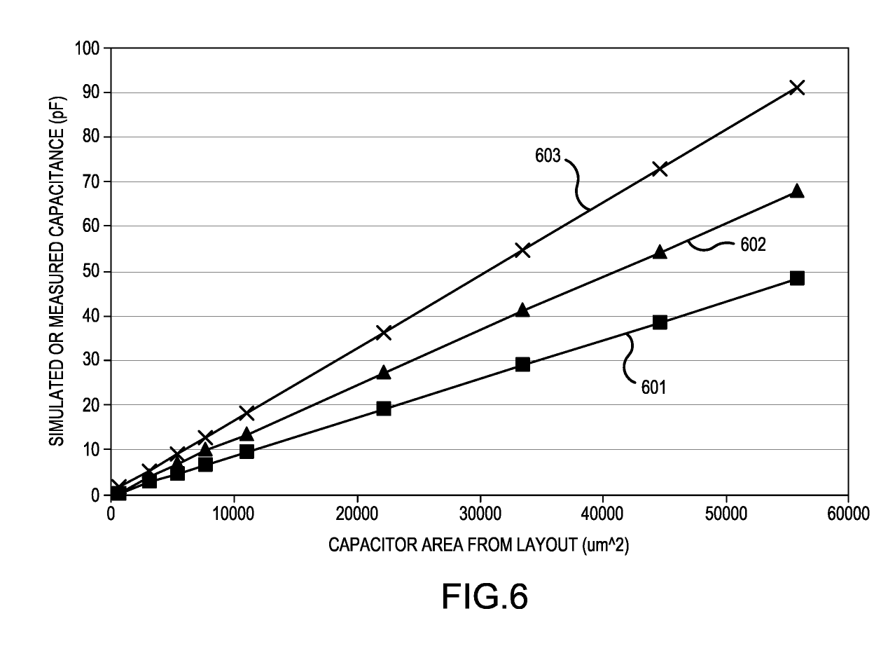

FIG. 6 is a graph showing the capacitance versus area of overlap of a known capacitor, and of capacitors of the present teachings.

Curve 601 shows the measured or simulated capacitance versus capacitor area of a known capacitor having a PECVD silicon nitride dielectric layer with a thickness of 710 Å.

Curve 602 shows the measured or simulated capacitance versus capacitor area of a capacitor in accordance with a representative embodiment, and comprising the first adhesion layers, the first and second barrier layers discussed above, a first passivation layer comprising 50 Å Si₃N₄, a 900 Å Ta₂O₅ dielectric layer, and a 50 Å Si₃N₄ second passivation layer. Notably, the dielectric layer of the capacitor of curve 602 was fabricated using a known sputtering method.

Curve 603 shows the measured or simulated capacitance versus expected capacitance of a capacitor in accordance with a representative embodiment, and comprising the first adhesion layers, the first and second barrier layers discussed above, a first passivation layer comprising 50 Å Si₃N₄, a 900 Å Ta₂O₅ dielectric layer, and a 50 Å Si₃N₄ second passivation layer. Notably, the dielectric layer of the capacitor of curve 603 was fabricated using atomic layer deposition (ALD).

As can be appreciated, for a particular capacitor area, the capacitance of curves 602 and 603 of the capacitors of the present teachings is significantly greater than that of the known capacitor. Moreover, the capacitor having the ALD dielectric layer has a substantially greater capacitance than the other capacitors. As noted above, Applicants surmise that the sputter deposited Ta₂O₅ and HfO₂, may not be as homogeneous as ALD deposited Ta₂O₅, and may result in a capacitance density that is less than that of ALD Ta₂O₅. However, the sputter deposited Ta₂O₅ of the capacitor of curve 602 provides a significant improvement in capacitance per unit area compared to the known capacitor of curve 601.

As can be appreciated, by the present teachings, a capacitor can be provided that has the same capacitance as a known capacitor having a PECVD silicon nitride dielectric layer, but having a significantly reduced area. Moreover, and as noted above, the breakdown voltage of the capacitors of the present teachings can be improved by increasing the thickness of the dielectric layer, allowing a compromise in the area of the capacitor and the breakdown voltage.

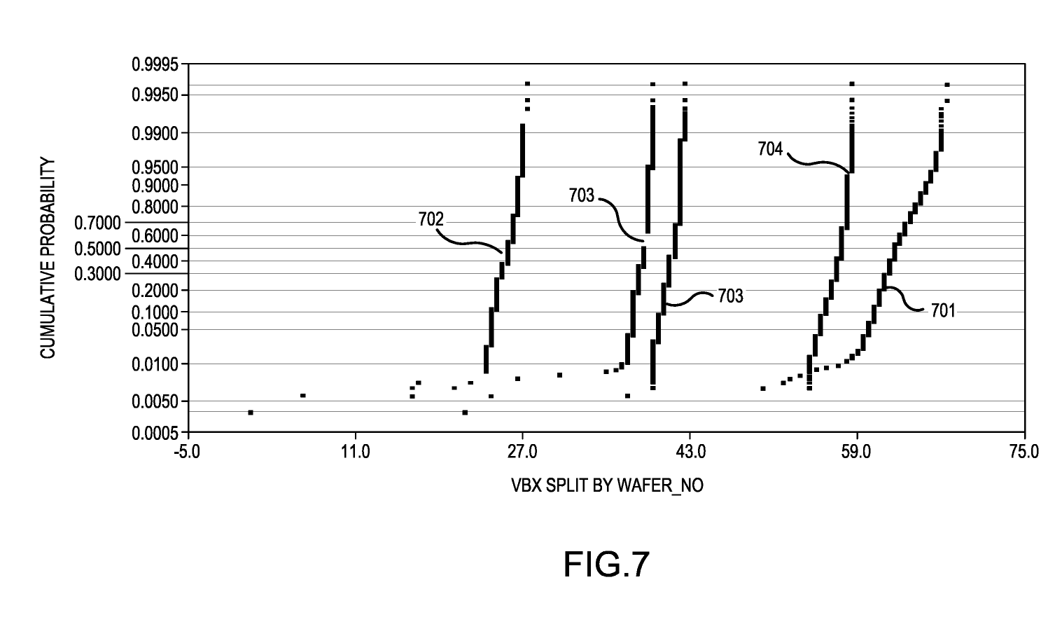

FIG. 7 is a graph showing breakdown voltage versus probability of a known capacitor, and of capacitors of the present teachings.

Curve 701 shows the breakdown voltage versus probability of a known capacitor having a PECVD silicon nitride dielectric layer.

Curve 702 shows the breakdown voltage versus probability of a capacitor in accordance with a representative embodiment, and comprising the first adhesion layers, the first and second barrier layers discussed above, a first passivation layer comprising 50 Å Si₃N₄, a 300 Å HfO₂ dielectric layer, and a 50 Å Si₃N₄ second passivation layer.

Curve 703 shows the breakdown voltage versus probability of a capacitor in accordance with a representative embodiment, and comprising the first adhesion layers, the first and second barrier layers discussed above, a first passivation layer comprising 50 Å Si₃N₄, a 300 Å Ta₂O₅ dielectric layer, and a 50 Å Si₃N₄ second passivation layer.

Curve 704 shows the breakdown voltage versus probability of a capacitor in accordance with a representative embodiment, and comprising the first adhesion layers, the first and second barrier layers discussed above, a first passivation layer comprising 50 Å Si₃N₄, a 610 Å Ta₂O₅ dielectric layer, and a 50 Å Si₃N₄ second passivation layer.

Curve 705 shows the breakdown voltage versus probability of a capacitor in accordance with a representative embodiment, and comprising the first adhesion layers, the first and second barrier layers discussed above, a first passivation layer comprising 50 Å Si₃N₄, a 950 Å Ta₂O₅ dielectric layer, and a 50 Å Si₃N₄ second passivation layer.

As can be appreciated, the breakdown voltage of the capacitors of the present teachings increases with increasing thickness of the high-k dielectric layer. As noted above, a desired breakdown voltage that is comparable to a known capacitor is realized by increasing the thickness of the dielectric layer (e.g., dielectric layer 110) of the present teachings, while still providing an improvement in the reduction of the capacitor area. By way of example, the thickness of the dielectric layer of capacitors of the present teachings can be selected to provide a similar breakdown voltage to that of a known capacitor having a PECVD S_{i3N4} dielectric layer, while having an areal dimension that is at least one-half of an area of the known capacitor having a PECVD S_{i3N4} dielectric layer, and having the same capacitance, and a similar magnitude breakdown voltage.

Moreover, and as can be seen from a review of FIG. 7, the slope of the breakdown voltage versus probability is greater for curves 702-705. Beneficially, by the present teachings, a greater distribution of capacitors exhibits the high intrinsic breakdown of the capacitors. The smaller the distribution of capacitors with breakdown below the intrinsic breakdown, the less the overall extrinsic defectivity of the capacitors.

In accordance with representative embodiments, a semiconductor structure having improved capacitors, and the improved capacitors themselves are described. One of ordinary skill in the art would appreciate that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A capacitor, comprising:
a first electrode;
a first barrier layer comprising silicon nitride (Si₃N₄) disposed over the first electrode;
a first platinum passivation layer disposed over the first electrode;
a first adhesion layer disposed over the first platinum passivation layer;
a dielectric layer comprising amorphous tantalum pentoxide (Ta₂O₅) or amorphous hafnium dioxide (HfO₂), the dielectric layer being disposed over the first platinum passivation layer;
a second platinum passivation layer disposed over the dielectric layer;
a second adhesion layer disposed over the second platinum passivation layer;
a second barrier layer comprising silicon nitride (Si₃N₄) disposed over the second adhesion layer; and
a second electrode disposed over the second barrier layer.

2. (canceled)

3. The capacitor of claim 1, wherein the dielectric layer has a dielectric constant in a range of approximately 20 to approximately 25.

4. The capacitor of claim 1, wherein the first and second adhesion layers comprise titanium.

5. The capacitor of claim 1, wherein the first and second silicon nitride barrier layers each have a thickness in a range of approximately 15.0 Å and approximately 50.0 Å.

6. The capacitor of claim 5, wherein the amorphous Ta₂O₅ dielectric layer has a thickness in a range of approximately 950.0 Å and approximately 1250.0 Å.

7. A semiconductor structure, comprising:
a III-V semiconductor mesa structure;
a first electrode disposed over the III-V semiconductor mesa structure;
a first barrier layer disposed over the first electrode;
a first adhesion layer disposed over the first electrode;
a first platinum passivation layer disposed over the first adhesion layer;
a dielectric layer disposed over the first passivation layer;
a second passivation layer disposed over the dielectric layer;
a second adhesion layer disposed over the second passivation layer;
a second barrier layer disposed over the second adhesion layer; and
a second electrode disposed over the second electrode.

8. The semiconductor structure as claimed in claim 7, wherein the dielectric layer comprises amorphous tantalum pentoxide (Ta₂O₅).

9. The semiconductor structure of claim 8, wherein the dielectric layer has a dielectric constant in a range of approximately 20 to approximately 25.

10. The semiconductor structure of claim 8, wherein the first and second barrier layers comprise silicon nitride (Si₃N₄), the first and second adhesion layers comprise titanium, and the second barrier layer is platinum.

11. The semiconductor structure of claim 10, wherein the first and second barrier layers of silicon nitride each have a thickness in a range of approximately 15.0 Å and approximately 50.0 Å.

12. The semiconductor structure of claim 11, wherein the amorphous Ta₂O₅ dielectric layer has a thickness in a range of approximately 950.0 Å and approximately 1250.0 Å.

13. A capacitor having a capacitance, the capacitor comprising:
a first electrode having an area;
a dielectric layer disposed over the first electrode, the dielectric layer having an area, and a relative permittivity that is in a range between approximately 3.1 times greater, and approximately 3.6 times greater than a relative permittivity of silicon nitride (Si₃N₄); and
a second electrode disposed over the dielectric layer, and having an area, wherein the area is one-half or less of an area of another capacitor having the capacitance, and comprising a silicon nitride dielectric layer.

14. The capacitor of claim 13, wherein the dielectric layer has a thickness that is greater than a thickness of the silicon nitride dielectric layer of the other capacitor.

15. The capacitor of claim 14, wherein a breakdown voltage of the capacitor is approximately a same as a breakdown voltage of the other capacitor.

16. The capacitor of claim 13, wherein the dielectric layer comprises amorphous tantalum pentoxide (Ta₂O₅).

17. The capacitor of claim 16, wherein the dielectric layer has a dielectric constant in a range of approximately 20 to approximately 25.

18. The capacitor of claim 16, further comprising:
a first barrier layer disposed over the first electrode;
a first adhesion layer disposed over the first electrode;
a first passivation layer disposed over the first adhesion layer;
a second passivation layer disposed over the dielectric layer;
a second adhesion layer disposed over the second passivation layer; and
a second barrier layer disposed over the second adhesion layer.

19. The capacitor of claim 18, wherein the first and second barrier layers comprise platinum, the first and second adhesion layers comprise titanium, and the first and second barrier layers comprise silicon nitride.

20. The capacitor of claim 19, wherein the first and second barrier layers reduce oxidation of the first and second adhesion layers comprising titanium, respectively, by the dielectric layer comprising tantalum pentoxide.

21. The capacitor of claim 13, wherein the dielectric layer comprises hafnium dioxide (HfO₂).

22. The capacitor of claim 13, wherein an area of overlap of the first electrode, the second electrode, and the dielectric layer is in a range between approximately 3.1 times smaller, and approximately 3.6 times smaller than the capacitor comprising the silicon nitride dielectric layer.
